(19) United States
(12) Patent Application Publication
(10) Pub. No.: US 2016/0143132 A1
(43) Pub. Date: May 19, 2016

(54) CIRCUIT BOARD AND METHOD OF MANUFACTURING THE SAME

(71) Applicant: Samsung Electro-Mechanics Co., Ltd, Suwon-si (KR)

(72) Inventors: Tae-Hong MIN, Hwaseong-si (KR); Myung-Sam KANG, Hwaseong-si (KR); Jung-Han LEE, Seoul (KR); Young-Gwan KO, Seoul (KR)

(73) Assignee: Samsung Electro-Mechanics Co., Ltd, Suwon-si (KR)

(21) Appl. No.: 14/937,625

(22) Filed: Nov. 10, 2015

(30) Foreign Application Priority Data
Nov. 13, 2014 (KR) 10-2014-0158257

(51) Int. Cl. H05K 1/02; H05K 3/00; H05K 3/18; H05K 1/11

(52) U.S. Cl. CPC H05K 1/0212; H05K 1/115; H05K 3/0094; H05K 3/18; H05K 2201/064

(57) ABSTRACT

A circuit board includes: a core portion comprising a fluid path, the fluid path being open toward an outside of the circuit board to allow a fluid outside the circuit board to pass through the fluid path; and insulation layers disposed above and below the core portion.

### CROSS-REFERENCE TO RELATED APPLICATION(S)

This application claims the benefit of Korean Patent Application No. 10-2014-0158257 filed in the Korean Intellectual Property Office on Nov. 13, 2014, the entire disclosure of which is incorporated herein by reference for all purposes.

### BACKGROUND

1. Technical Field

The following description relates to a circuit board and a method of manufacturing a circuit board.

2. Description of Related Art

Multi-layer board technologies, in which a plurality of wiring layers are formed on a circuit board such as a printed circuit board (PCB), have been developed to cope with electronic devices that have increasingly become lighter, smaller and faster with more functions and higher performances. Furthermore, technologies have been developed to mount electronic components, for example, active devices or passive devices, on a multi-layer board.

Moreover, as application processors (AP) connected to the multi-layer boards have been equipped with more functions and higher performances, heat generation has been significantly increased. Accordingly, there have been efforts to reduce the heat generation or improve heat-dissipating properties.

A multi-layer circuit board is disclosed in KR 10-2013-0098001 A.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

According to one general aspect, a circuit board includes: a core portion including a fluid path, the fluid path being open toward an outside of the circuit board to allow a fluid outside the circuit board to pass through the fluid path; and insulation layers disposed above and below the core portion.

The fluid path may be arranged in two or more rows, respectively, in an upper portion and a lower portion of the core portion.

The circuit board of claim 1, wherein the fluid path includes an inlet and an outlet arranged on lateral surfaces of the core portion.

The circuit board may further include: a first via extending through the core portion and forming an electrical connection between an upper surface of the core portion and a lower surface of the core portion; and an insulation film disposed between an external surface of the first via and a surface of the core portion, wherein the core portion is constructed of a metallic material.

According to another general aspect, a circuit board includes: a core portion including a fluid path through which a fluid is allowed to pass, and a frame portion constructed of a metallic material and forming an external wall of the fluid path; an insulation film disposed on an external surface of the core portion; a circuit pattern disposed on a surface of the insulation film; a first insulation layer disposed on the core portion and having a conductive pattern arranged on an external surface thereof; and a via extending through the first insulation layer and connecting the circuit pattern with the conductive pattern.

The circuit board may further include: a first via extending through the core portion between an upper side of the core portion and a lower side of the core portion; a first upper conductive pattern disposed on an upper surface of the first via; and a first lower conductive pattern disposed on a lower surface of the first via, wherein the insulation film is disposed between a surface of the core portion and each of the first via, the first upper conductive pattern and the first lower conductive pattern.

The circuit board may further include a second insulation layer covering the conductive pattern and the external surface of the first insulation layer, wherein at least a portion of the conductive pattern is exposed to an outside of the second insulation layer.

The circuit board may further include: a solder ball coupled to the at least a portion of the conductive pattern exposed to the outside of the second insulation layer; and an electronic component electrically connected to the conductive pattern by the solder ball.

According to another general aspect, a method of manufacturing a circuit board includes: forming a first resist pattern on a seed layer; performing a first plating process to form a first frame portion covering an upper surface of the first resist pattern and a surface of the seed layer exposed to an outside of the first resist pattern; and forming a fluid path by removing the first resist pattern.

The removing of the first resist pattern may include combusting the first resist pattern.

The combusting of the first resist pattern may include combusting the first resist pattern under a high temperature and vacuum condition.

The method may further include, between the performing of the first plating process and the forming of the fluid path, forming a second resist pattern on the first frame portion and then performing a second plating process to form an second frame portion covering an upper surface of the second resist pattern and a surface of the first frame portion exposed to an outside of the second resist pattern.

The method may further include: forming a first via hole resist pattern above the second frame portion; forming a second via hole resist pattern below the first frame portion; forming a via hole by etching a portion of the second frame portion uncovered by the first via hole resist pattern from an upper side of the second frame portion and etching a portion of the first frame portion uncovered by the second via hole resist pattern from a lower side of the first frame portion; and filling a conductive material in the via hole.

The via hole may have an hourglass shape.

The method may further include: forming a via hole resist pattern on the first frame portion; forming a via hole by etching a portion of the first frame portion uncovered by the via hole resist pattern; removing the via hole resist pattern and then forming an insulation film on an external surface of the first frame portion; and filling a conductive material in the via hole. The forming of the insulation film on the external surface of the first frame portion may be performed by a dip coating method or a vapor deposition method.

Other features and aspects will be apparent from the following detailed description, the drawings, and the claims.

### BRIEF DESCRIPTION OF DRAWINGS

FIG. 1 is a cross-sectional view illustrating a circuit board according to an example.

FIG. 2 is a perspective view illustrating a portion of the circuit board of FIG. 1.

FIG. 3 is a cross-sectional view of the circuit board of FIG. 1 shown along the line I-I′.

FIGS. 4A-4G illustrate the formation of a core portion in an example method of manufacturing the circuit board, wherein FIG. 4A shows a state in which a seed layer is provided, FIG. 4B shows a state in which a resist layer is formed, FIG. 4C shows a state in which a resist pattern is formed, FIG. 4D shows a state in which a frame portion is formed, FIG. 4E shows a state in which an additional resist pattern is formed, FIG. 4F shows a state in which an additional frame portion is formed, and FIG. 4G shows a state in which the resist pattern inside the frame portion is removed and fluid paths are formed.

FIGS. 5A-5D illustrate the formation of a first via hole in the method of manufacturing the circuit board, according to an example, wherein FIG. 5A shows a state in which a resist pattern is formed on the core portion, FIG. 5B shows a state in which a first via hole is formed, FIG. 5C shows a state in which the resist pattern is removed, and FIG. 5D shows a state in which an insulation film is formed.

FIGS. 6A-6D illustrate the formation of a first via in the method of manufacturing the circuit board, according to an example, wherein FIG. 6A shows a state in which the core portion having the first via hole formed therein is provided, FIG. 6B shows a state in which a resist pattern is formed, FIG. 6C shows a state in which a conductive material is filled in, and FIG. 6D shows a state in which the resist pattern is removed.

FIGS. 7A-FIG. 7E illustrate the formation of a buildup insulation layer and circuit patterns on the core portion in the method of manufacturing a circuit board, according to an example, wherein FIG. 7A shows a state in which a first upper insulation layer and a first lower insulation layer are formed, FIG. 7B shows a state in which a via hole is formed, FIG. 7C shows a state in which a via and a conductive pattern are formed, FIG. 7D shows a state in which a second upper insulation layer and a second lower insulation layer are formed, and FIG. 7E shows a state in which a first electronic component is coupled to the conductive pattern.

Throughout the drawings and the detailed description, the same reference numerals refer to the same elements. The drawings may not be to scale, and the relative size, proportions, and depiction of elements in the drawings may be exaggerated for clarity, illustration, and convenience.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent to one of ordinary skill in the art. The sequences of operations described herein are merely examples, and are not limited to those set forth herein, but may be changed as will be apparent to one of ordinary skill in the art, with the exception of operations necessarily occurring in a certain order. Also, descriptions of functions and constructions that are well known to one of ordinary skill in the art may be omitted for increased clarity and conciseness.

The features described herein may be embodied in different forms, and are not to be construed as being limited to the examples described herein. Rather, the examples described herein have been provided so that this disclosure will be thorough and complete, and will convey the full scope of the disclosure to one of ordinary skill in the art.

Terms such as “left,” “right,” “front,” “behind,” “top,” “bottom,” “above,” “below,” etc. are used in the description and the claims for the purpose of description only and are not necessarily used for defining invariable relative positions. It shall be appreciated that these terms may be compatibly used for description of other orientations than the orientations described herein under a proper environment. Terms used in the effect of being “connected” shall be used to define a connection in an electrical or non-electrical fashion, either directly or indirectly. Any objects described as being “adjacent” to one another may be properly in physical contact with, in proximity to, or in a same general range or region of one another.

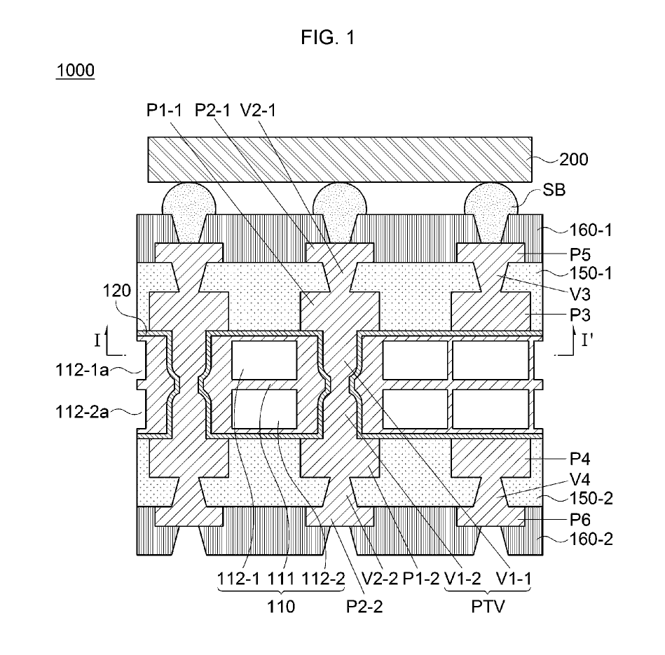

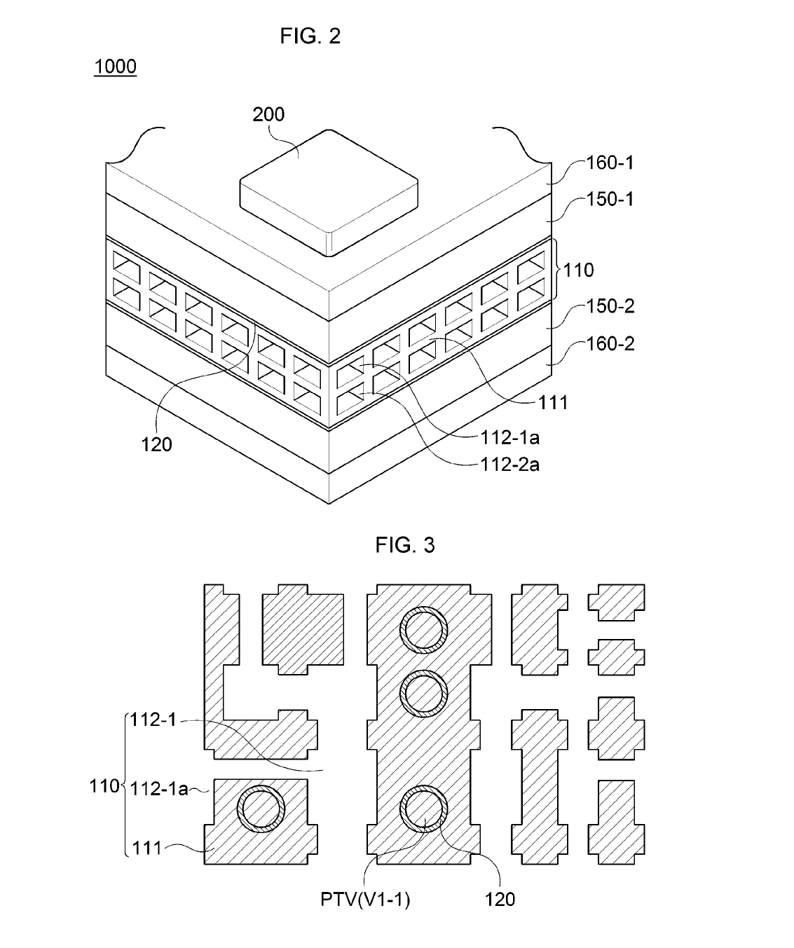

FIG. 1 is a cross-sectional view illustrating a circuit board 1000 according to an example. FIG. 2 is a perspective view illustrating a portion of the circuit board 1000 according to an example, and FIG. 3 is a cross-sectional view of the circuit board 1000 shown along the line I-I′ of FIG. 1.

Referring to FIG. 1, the circuit board 1000 includes a core portion 110 having a fluid path provided therein. Cooling gas, such as air, or cooling water is flowed into the core portion 110 through the fluid path, thereby cooling the core portion 110 quickly. Accordingly, heat from the circuit board 1000 is dissipated quickly through the core portion 110.

In an embodiment, the core portion 110 includes a frame portion 111 made of a metallic material. Accordingly, the core portion 110 may have an improved heat conductivity, and when a section of the core portion 110 is heated, the heat may be quickly transferred to another section of the core portion 110. Moreover, through heat exchange between a fluid moving through the fluid path provided in the core portion 110 and the frame portion 111, heat dissipation may be efficiently carried out throughout the core portion 110.

The core portion 110 may have a buildup layer formed thereon, if necessary. The buildup layer includes a conductive pattern and an insulation layer. Referring to FIG. 1, a first upper conductive pattern P1-1, a first circuit pattern P3 and a first upper insulation layer 150-1 are provided on an upper surface of the core portion 110. A first lower conductive pattern P1-2, a second conductive pattern P4 and a first lower insulation layer 150-2 are further provided on a lower surface of the core portion 110. Moreover, a second upper conductive pattern P2-1 and a first conductive pattern P5 are provided on an upper surface of the first upper insulation layer 150-1, and a second lower conductive pattern P2-2 and a second conductive pattern P6 are provided on a lower surface of the first lower insulation layer 150-2. Furthermore, a second upper insulation layer 160-1 is disposed to cover the upper surface of the first upper insulation layer 150-1, the second upper conductive pattern P2-1 and the first conductive pattern P5, and a second lower insulation layer 160-2 is disposed to cover the lower surface of the first lower insulation layer 150-2, the second lower conductive pattern P2-2 and the second conductive pattern P6.

Although described with different terms, the first upper conductive pattern P1-1, the first circuit pattern P3, the second upper conductive pattern P2-1, the first conductive pattern P5, the first lower conductive pattern P1-2, the second circuit pattern P4, the second lower conductive pattern P2-2 and the second conductive pattern P6 are all conductive patterns, each of which is made of a conductive material. Moreover, although not illustrated in cross-sectional views, including FIG. 1, conductive patterns may form a predetermined circuit by being electrically connected with or insulated from one another through various routes. That is, the conductive patterns may be electrically connected with one another through a second upper via V2-1, a second lower via V2-2, a third via V3, a fourth via V4, etc., and electrical connections in horizontal directions or vertical directions may be made by other conductive patterns that are not illustrated in cross-sectional views, including FIG. 1.

Moreover, the second upper insulation layer 160-1 and the second lower insulation layer 160-2 may each have an insulation layer and a conductive pattern layer provided thereon, if necessary.

However, in the case where the second upper insulation layer 160-1 and the second insulation layer 160-2 are outermost insulation layers of the circuit board 1000 as illustrated, the second upper insulation layer 160-1 and the second insulation layer 160-2 may be formed of solder resist. In such a case, the second upper insulation layer 160-1 may expose at least a portion of conductive patterns thereunder, namely, the second upper conductive pattern P2-1 and the first conductive pattern P5. Accordingly, the portion exposed outside through the second upper insulation layer 160-1 may be connected with a device 200, for example, which may be any one of various electronic components such as an active device, a passive device and another substrate. Here, the portion of the second upper conductive pattern P2-1 or the first conductive pattern P5 exposed outside through the second upper insulation layer 160-1 may have a surface treatment part (not shown), for example, nickel-gold alloy, provided thereon, and may be coupled physically/electrically with the first electronic component 200 by a solder ball SB or a wire (not shown). As a result, the second upper conductive pattern P2-1 or the first conductive pattern P5 is capable of carrying out the function of a contact pad. Although an upper part of the core portion 110 has been described hitherto, similar elements (e.g., the solder ball SB and the device 200) may be provided on a lower part of the core portion 110.

Meanwhile, in the case where the core portion 110 is made of a metallic material, a conductive pattern might be connected through an unintended route if the conductive pattern were to make direct contact with a surface of the core portion 110, possibly causing a short circuit. In an embodiment, in order to prevent such a short circuit, an insulation film 120 is provided between the surfaces of the core portion 110 and the first upper conductive pattern P1-1, the first lower conductive pattern P1-2, the first circuit pattern P3 and the second circuit pattern P4. The insulation film 120 may be formed by coating an insulation material on the surface of the core portion 110 through a dip coating method or a vapor deposition method. Accordingly, the insulation film 120 may form a very thin form, unlike other insulation layers, but provide insulation. Moreover, forming the thin insulation film 120 may contribute to making the circuit board 1000 slim and to improving the heat-dissipating performance through the core portion 110.

In an embodiment, a first via PTV, which penetrates the core portion 110 between the upper surface thereof and the lower surface thereof, and which may be referred to as a core-penetrating via, is provided.

When the core portion 110 is made of a metallic material, an unintended electrical connection might be made if the core portion 110 and the first via PTV were in direct contact with each other. Therefore, in the case where the core portion 110 is made of a metallic material, the above-described insulation film 120 is provided between the core portion 110 and the first via PTV to prevent the short-circuit problem.

In an embodiment, the first via PTV includes a first upper via V1-1 and a first lower via V1-2. Specifically, in the case where the metallic core portion 110 is relatively thick between the lower surface thereof and the upper surface thereof, a via hole for the first upper via V-1 and a via hole for the first lower via V1-2 may be formed, respectively, by etching the core portion 110 from the upper surface thereof toward the lower surface thereof and etching the core portion 110 from the lower surface thereof toward the upper surface thereof. By etching the core portion 110 in both directions, the first via PTV may be formed in an hourglass shape. This way of forming the first via PTV may prevent the first via PTV from having an excessively large diameter, compared to forming the first via PTV by etching the core portion 110 in one direction only, thereby possibly contributing to minimizing a pitch or a width of the circuit pattern.

Referring to FIG. 1, in an embodiment, the first via PTV electrically/physically connects the first upper conductive pattern P1-1 to the first lower conductive pattern P1-2. Moreover, if necessary, the second upper via V2-1, which penetrates the first upper insulation layer 150-1, electrically/physically connects the first upper conductive pattern P1-1 to the second upper conductive pattern P2-1. Furthermore, the second lower via V2-2 electrically/physically connects the first lower conductive pattern P1-2 to the second lower conductive pattern P2-2.

Lateral surfaces of the core portion 110, not the upper and lower surfaces thereof, may be exposed to an outside of the circuit board 1000. That is, the lateral surfaces of the core portion 110 may be exposed at lateral surfaces of the circuit board 1000.

Moreover, the fluid path passing through the core portion 110 is open toward the lateral surfaces of the core portion 110 at end portions 112-1a and 112-2a of the core portion that are exposed at the lateral surfaces of the circuit board 1000, as shown in FIGS. 1 and 2. A fluid is flowed into the fluid path inside the core portion 110 through a portion opened to the outside of the circuit board 1000 and is then flowed out through another portion opened to the outside of the circuit board 1000 after having passed through the fluid path. In this sense, it may be understood that the fluid path includes an inlet and an outlet.

The fluid path may be arranged uniformly throughout the circuit board 1000. Moreover, if a particular section of the circuit board 1000 has a higher temperature than other sections thereof, and thus heat of the particular section needs to be removed rather quickly, the fluid path may be formed in the particular section with a greater density. Here, when designing the fluid path, it is necessary to consider the position of the first via PTV or the like. That is, if the fluid path were placed at a region where the first via PTV is to be formed, the first via PTV would not be formed properly, and the first via PTV would not be able to perform its intended function stably.

Moreover, a plurality of fluid paths may be provided, and the plurality of fluid paths may be arranged in an upper portion and a lower portion of the core portion 110. FIG. 1 illustrates that a first fluid path 112-1 is placed in the upper portion of the core portion 110 and a second fluid path 112-2 is placed in the lower portion of the core portion 110. Although FIG. 1 shows that there are two fluid paths provided in the core portion 110, it is possible that a greater number of fluid paths are provided in the core portion 110, if necessary.

In an embodiment, the core portion 110 prevents warpage of the circuit board 1000 as well as dissipates heat. Accordingly, the core portion 110 may be made of a material that has not only a high thermal conductivity but also a low coefficient of thermal expansion and a high rigidity. Moreover, the greater the proportion of the overall volume of the fluid paths to the overall volume of the core portion 110, the lower the rigidity of the core portion 110 may be. That is, the smaller the thickness of each frame portion 111 or the overall volume of the frame portion 111 becomes, the less resistant the circuit board 1000 becomes to warpage. Nevertheless, by implementing the frame portion 111 in a truss or grid structure, the rigidity of the core portion 110 may be enhanced for a given volume of the frame portion 111. Moreover, when designing the arrangement of the fluid paths as described above, the fluid paths may be arranged with a lower density at a section having a relatively high stress caused by warpage of the circuit board 1000 and may be arranged with a higher density at a section having a relatively high temperature. That is, the arrangement of the fluid paths may be designed by considering the overall paths of conduction, heat distribution and stress associated with warpage of the circuit board 1000.

As a result, the heat dissipating performance of the circuit board 1000 may be improved, and the warpage issue of the circuit board 1000 may be mitigated.

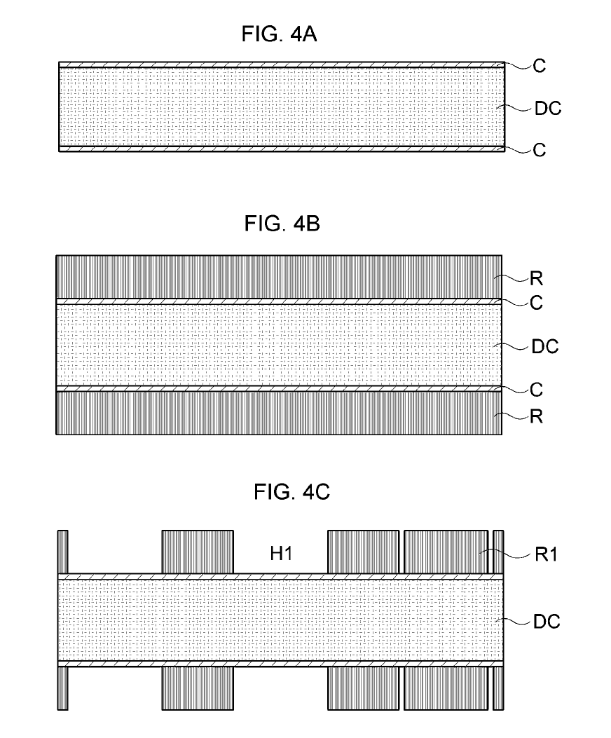

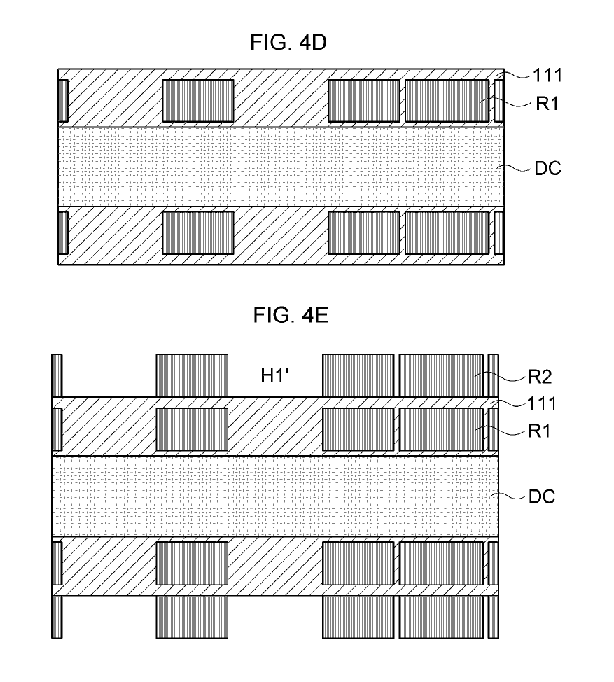

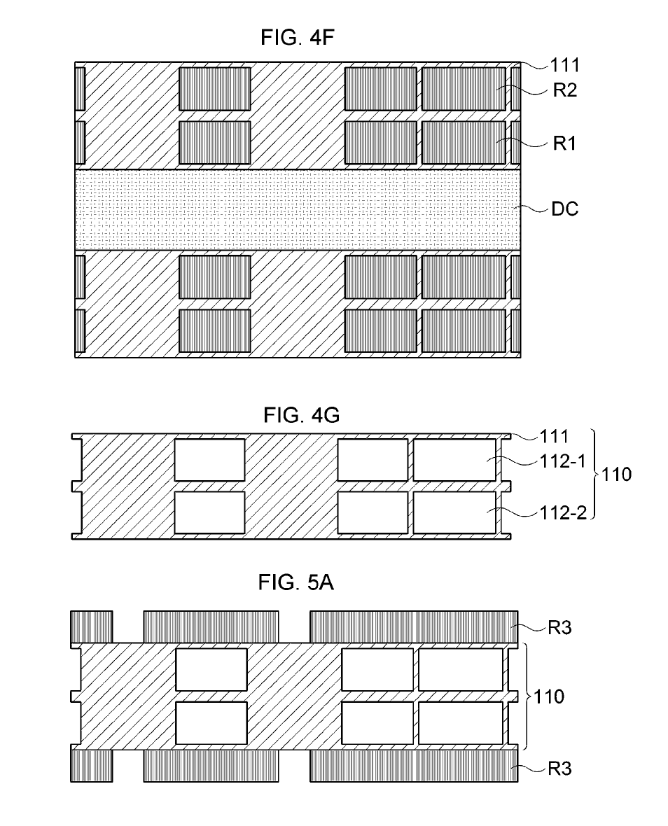

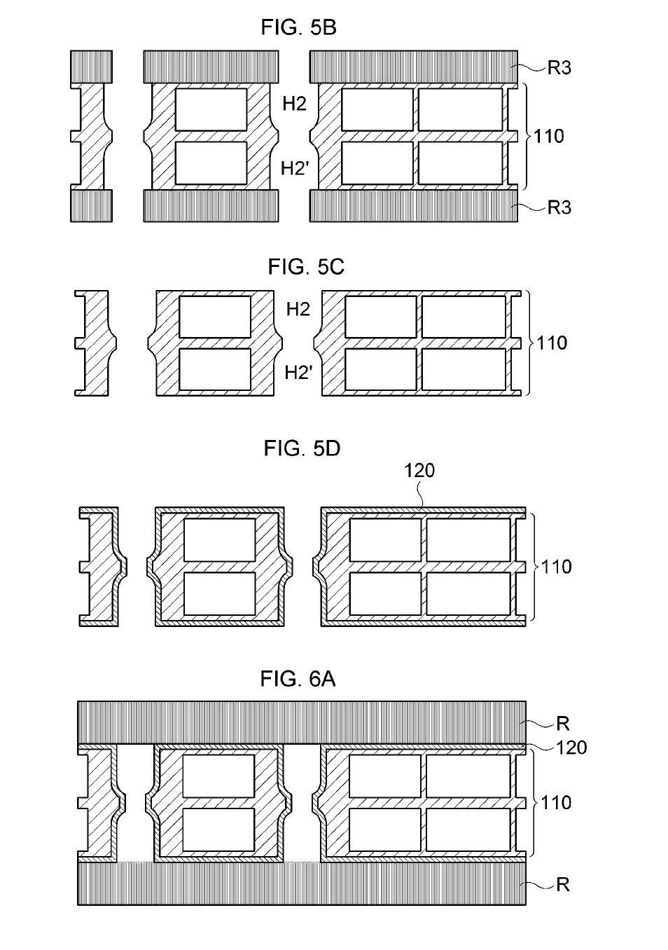

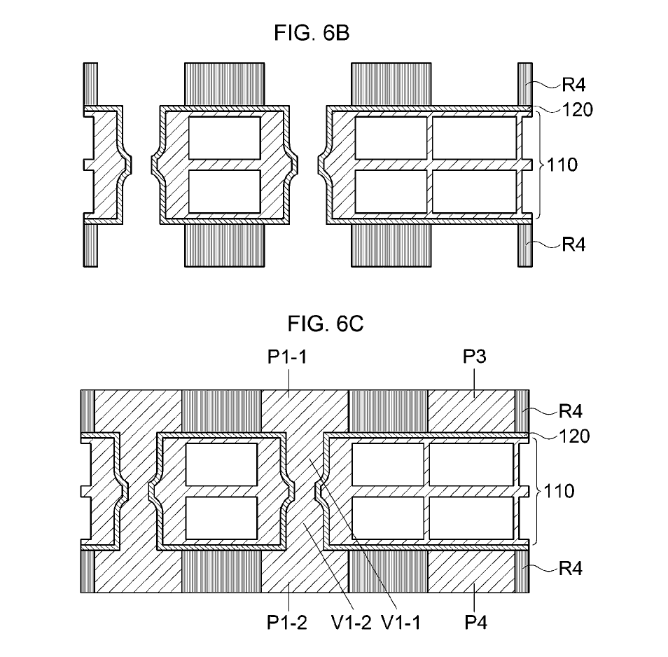

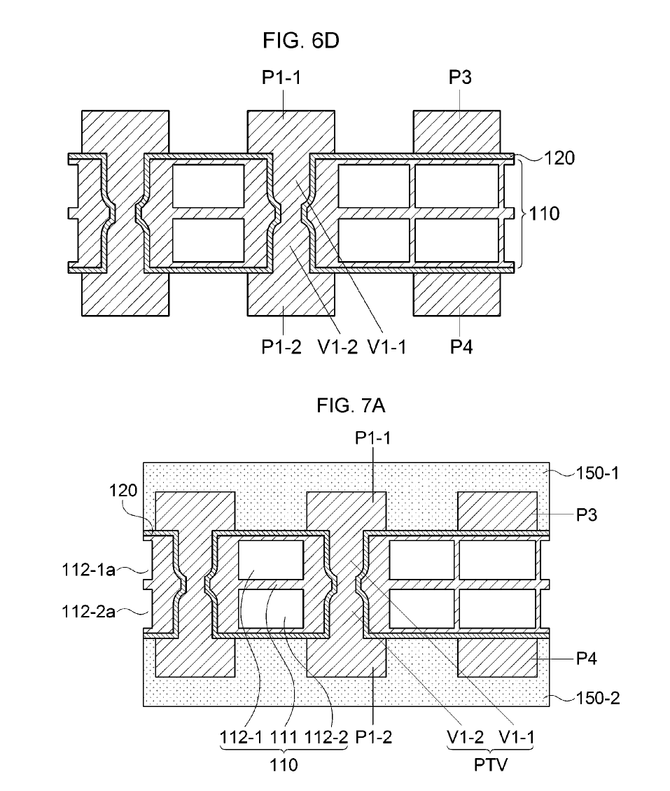

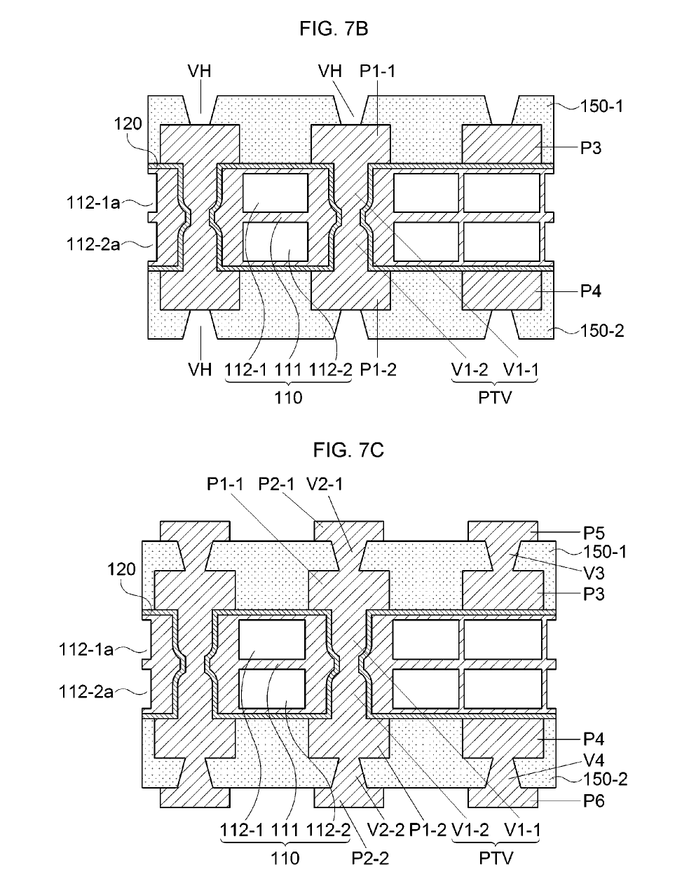

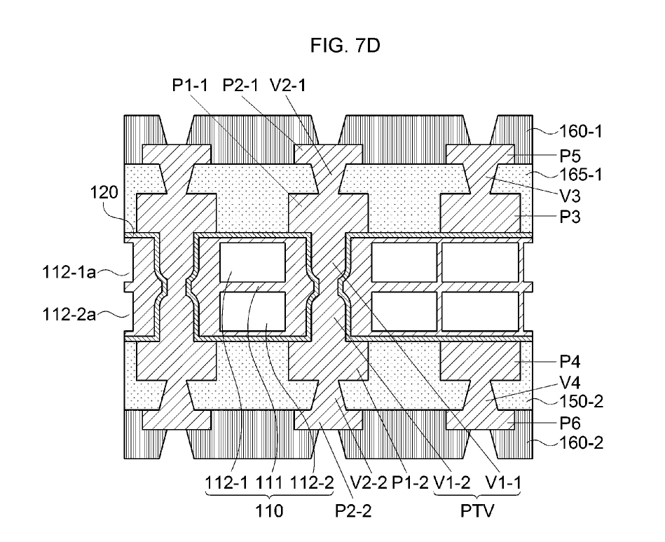

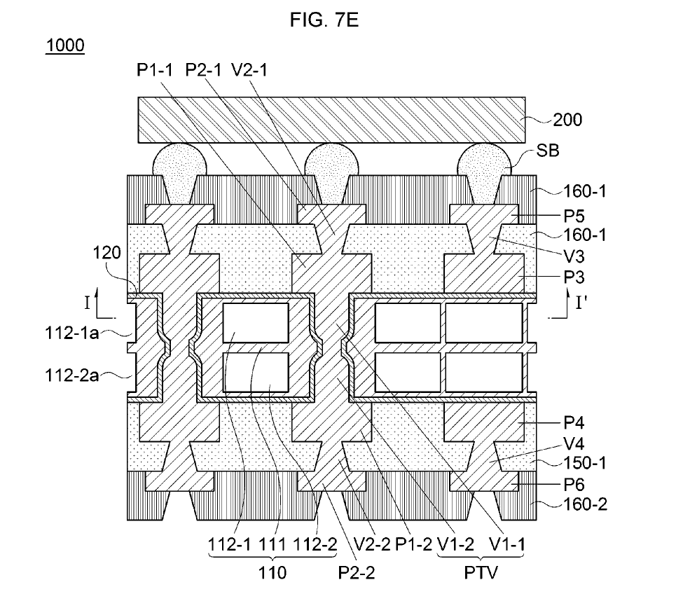

FIGS. 4A-4G illustrate an example process of forming the core portion 110 in a method of manufacturing the circuit board 1000. FIGS. 5A-5D illustrate an example process of forming a first via hole the method of manufacturing the circuit board 1000. FIGS. 6A-6D illustrate an example process of forming the first via PTV in the method of manufacturing the circuit board 1000. FIGS. 7A-7E illustrate an example process of forming a buildup insulation layer and circuit patterns on the core portion 110 in the method of manufacturing the circuit board 1000.

Hereinafter, the method of manufacturing the circuit board 1000 in accordance with an embodiment will be described with reference to FIGS. 4A-7E.

First, a resist pattern is formed on a seed layer. Here, as illustrated in FIG. 4A, a resist pattern R1 is formed by: forming a copper clad laminate (CCL) by forming a copper foil C on both surfaces of a detachable core DC, as shown in FIG. 4A; forming a resist layer R on the CCL, as shown in FIG. 4B; and removing a portion of the resist layer R at a region H1 of the resist layer R where a frame portion 111 is to be formed, as shown in FIG. 4C.

Then, referring to FIG. 4D, a plating process is performed to form a plated portion in the region H1 of the seed layer exposed out of the resist pattern R1 and over the resist pattern R1. Later, the plated portion forms at least a part of the frame portion 111. Here, follow-up processes may be carried out while the resist pattern R1 is removed. It is also possible that the follow-up processes are performed while the resist pattern R1 remains unremoved and stays inside the frame portion 111.

Moreover, as described above, fluid paths may be formed in multiple layers, if necessary, in which case an additional resist pattern R2 is formed, as shown in FIG. 4E. The additional resist pattern R2 is formed by removing a resist material at a region H1′ where an additional frame portion 111 is to be formed.

Next, as shown in FIG. 4F, a plating process is performed to form a plated portion in the region H1′ on a surface of the frame portion 111 exposed out of the additional resist pattern R2 and over the additional resist pattern R2. Later, the plated portion over the resist pattern R2 forms part of the frame portion 111.

Afterwards, as shown in FIG. 4G, the frame portion 111 is separated from the detachable core DC, and then the additional resist pattern R2 and/or the resist pattern R1 that remain inside the frame portion 111 are removed. Here, removing the additional resist pattern R2 and/or the resist pattern R1 by use of a conventional chemical method may be quite inefficient because the additional resist pattern R2 and/or the resist pattern R1 are surrounded by the frame portion 111. Accordingly, the additional resist pattern R2 and/or the resist pattern R1 remaining inside the frame portion 111 may be removed by use of a combustion method. In addition, the additional resist pattern R2 and/or the resist pattern R1 may be combusted under a high-temperature, vacuum condition for an improved efficiency.

By having the resist patterns remaining inside the frame portion 111 removed, the fluid paths are formed in the core portion 110. Although it is described herein based on the core portion 110 that includes a first fluid path 112-1 and a second fluid path 112-2, a similar method may be used even if a single layer of fluid paths is provided or 3 or more layers of fluid paths are provided. Moreover, in the case of providing multiple layers of fluid paths, the resist pattern R1 and the additional resist pattern R2 may be removed simultaneously in a same process.

Next, referring to FIG. 5A, a resist pattern R3 is formed on top and bottom surfaces of the core portion 110 having the fluid paths provided therein, and as shown in FIG. 5B, via holes H2, H2′ are formed by injecting an etchant into a portion of the core portion 110 where the resist pattern R3 is removed and etching the frame portion 111 of the core portion 110. Here, the via holes H2, H2′ are for forming the first via PTV as described above, and thus may be referred to as first via holes.

Then, as shown in FIG. 5C, the resist pattern R3 is removed.

Since the core portion 110 includes the frame portion 111 made of a metallic material, insulation is required between the first via PTV and the surface of the core portion 110.

Therefore, as illustrated in FIG. 5D, an insulation film 120 is formed on the surfaces of the core portion 110. Here, the insulation film 120 may be formed by use of a dip coating method or a vapor deposition method. Accordingly, the insulation film 120 is provided in the first via hole as well as on an upper surface and a lower surface of the core portion 110 through a single process. Here, since insulation is not required inside the fluid paths, the process of forming the insulation film 120 may be performed while inlets and outlets of the fluid paths are shielded by, for example, a coating film.

Thereafter, as illustrated in FIG. 6A, a resist layer R is formed on the core portion 110 having the insulation film 120 provided thereon. Then, as shown in FIG. 6B, material of the resist layer R formed on the core portion 110 having the insulation film 120 provided thereon is removed at a region where the first via PTV is to be formed. In this process, the material of the resist layer at other regions where a conductive pattern is to be formed may be also removed, thereby forming a resist pattern R4.

Next, as illustrated in FIG. 6C, a conductive material is filled in open regions of the resist pattern R4 to form the first via PTV, a first upper conductive pattern P1-1, a first lower conductive pattern P1-2, a first circuit pattern P3, a second circuit pattern P4. Here, the conductive material may be filled in by use of various methods, including a printing method, a plating method, etc.

Then, as shown in FIG. 6D, the resist pattern R4 is removed, and as shown in FIG. 7A, a first upper insulation layer 150-1 is formed over the first upper conductive pattern P1-1 and the first circuit pattern P3, and a first lower insulation layer 150-2 is formed over the first lower conductive pattern P1-2 and the second circuit pattern P4. Here, lateral surfaces of the core portion 110 may remain exposed to an outside.

After forming the via holes VH at portions of the first upper insulation layer 150-1 and the first lower insulation layer 150-2 where electrical connection is required, as shown in FIG. 7B, a second upper via V2-1, a second lower via V2-2, a third via V3 and a fourth via V4 are formed, as shown in FIG. 7C. In this process, a second upper conductive pattern P2-1, a second lower conductive pattern P2-2, a first conductive pattern P5 and a second conductive pattern P6 may be also formed.

Thereafter, as shown in FIG. 7D, a second upper insulation layer 160-1 is formed over the second upper via V2-1 and the third via V3, and a second lower insulation layer 160-2 is formed over the second lower via V2-2 and the fourth via V4. Then, if necessary, an electronic component 200 may be coupled to an exposed portion of the second upper conductive pattern P2-1 and an exposed portion of the first conductive pattern P5, as shown in FIG. 7E. Alternatively, or additionally, an electronic component 200 may be coupled to an exposed portion of the second lower conductive pattern P2-2 and an exposed portion of the second conductive pattern P6.

While this disclosure includes specific examples, it will be apparent to one of ordinary skill in the art that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents. Therefore, the scope of the disclosure is defined not by the detailed description, but by the claims and their equivalents, and all variations within the scope of the claims and their equivalents are to be construed as being included in the disclosure.

What is claimed is:

1. A circuit board comprising:
a core portion comprising a fluid path, the fluid path being open toward an outside of the circuit board to allow a fluid outside the circuit board to pass through the fluid path; and
insulation layers disposed above and below the core portion.

2. The circuit board of claim 1, wherein the fluid path is arranged in two or more rows, respectively, in an upper portion and a lower portion of the core portion.

3. The circuit board of claim 1, wherein the fluid path comprises an inlet and an outlet arranged on lateral surfaces of the core portion.

4. The circuit board of claim 1, further comprising
a first via extending through the core portion and forming an electrical connection between an upper surface of the core portion and a lower surface of the core portion; and
an insulation film disposed between an external surface of the first via and a surface of the core portion,
wherein the core portion is constructed of a metallic material.

5. A circuit board comprising:
a core portion comprising a fluid path through which a fluid is allowed to pass, and a frame portion constructed of a metallic material and forming an external wall of the fluid path;
an insulation film disposed on an external surface of the core portion;
a circuit pattern disposed on a surface of the insulation film;
a first insulation layer disposed on the core portion and having a conductive pattern arranged on an external surface thereof; and
a via extending through the first insulation layer and connecting the circuit pattern with the conductive pattern.

6. The circuit board of claim 5, further comprising:
a first via extending through the core portion between an upper side of the core portion and a lower side of the core portion;
a first upper conductive pattern disposed on an upper surface of the first via; and
a first lower conductive pattern disposed on a lower surface of the first via,
wherein the insulation film is disposed between a surface of the core portion and each of the first via, the first upper conductive pattern and the first lower conductive pattern.

7. The circuit board of claim 6, further comprising a second insulation layer covering the conductive pattern and the external surface of the first insulation layer, wherein at least a portion of the conductive pattern is exposed to an outside of the second insulation layer.

8. The circuit board of claim 7, further comprising:
a solder ball coupled to the at least a portion of the conductive pattern exposed to the outside of the second insulation layer; and
an electronic component electrically connected to the conductive pattern by the solder ball.

9. A method of manufacturing a circuit board, comprising:
forming a first resist pattern on a seed layer;
performing a first plating process to form a first frame portion covering an upper surface of the first resist pattern and a surface of the seed layer exposed to an outside of the first resist pattern; and
forming a fluid path by removing the first resist pattern.

10. The method of claim 9, wherein the removing of the first resist pattern comprises combusting the first resist pattern.

11. The method of claim 10, wherein the combusting of the first resist pattern comprises combusting the first resist pattern under a high temperature and vacuum condition.

12. The method of claim 9, further comprising, between the performing of the first plating process and the forming of the fluid path, forming a second resist pattern on the first frame portion and then performing a second plating process to form an second frame portion covering an upper surface of the second resist pattern and a surface of the first frame portion exposed to an outside of the second resist pattern.

13. The method of claim 12, further comprising:
forming a first via hole resist pattern above the second frame portion;
forming a second via hole resist pattern below the first frame portion;
forming a via hole by etching a portion of the second frame portion uncovered by the first via hole resist pattern from an upper side of the second frame portion and etching a portion of the first frame portion uncovered by the second via hole resist pattern from a lower side of the first frame portion; and
filling a conductive material in the via hole.

14. The method of claim 13, wherein the via hole has an hourglass shape.

15. The method of claim 9, further comprising:
forming a via hole resist pattern on the first frame portion;
forming a via hole by etching a portion of the first frame portion uncovered by the via hole resist pattern;
removing the via hole resist pattern and then forming an insulation film on an external surface of the first frame portion; and
filling a conductive material in the via hole.

16. The method of claim 15, wherein the forming of the insulation film on the external surface of the first frame portion is performed by a dip coating method or a vapor deposition method.
